(19) United States
(12) Patent Application Publication
(10) Pub. No.: US 2012/0256695 A1
(43) Pub. Date: Oct. 11, 2012

(54) BASE SUBSTRATE, RESONATOR, OSCILLATOR, AND ELECTRONIC DEVICE

(75) Inventor: Katsumi KURODA, Kamiina (JP)

(73) Assignee: SEIKO EPSON CORPORATION, Tokyo (JP)

(21) Appl. No.: 13/441,324

(22) Filed: Apr. 6, 2012

(30) Foreign Application Priority Data
Apr. 7, 2011 (JP) 2011-085160

(51) Int. Cl. H03B 1/00; H05K 1/09

(52) U.S. Cl. 331/68; 174/257

(57) ABSTRACT

A package of a quartz resonator includes a tabular base substrate, a base material of which is a single layer, a lid section that has a recess and covers the base substrate, and a bonding material provided over the entire periphery of one principal plane of the base substrate and including low-melting glass for bonding the base substrate and the lid section. Internal electrodes are provided on the one principal plane of the base substrate. External electrodes are provided on the other principal plane of the base substrate. A wire contains an Ag—Pd alloy having a glass component and crosses the bonding material on the one principal plane.

### BACKGROUND

1. Technical Field

The present invention relates to a package, a resonator including a resonator element in the package, an oscillator, and an electronic device.

2. Related Art

In the past, as a package used in a piezoelectric device such as a piezoelectric resonator, a semiconductor device, and the like, a package is known in which an internal electrode is provided on a package substrate formed in a tabular shape of a single layer using a ceramic material and the internal electrode and an external electrode provided on a bottom surface of the package substrate are connected via a conductive line that pierces through the package substrate (see, for example, JP-A-9-283650).

In the package, the package substrate (hereinafter referred to as a base section) is formed in the tabular shape of the single layer for the purpose of reducing manufacturing costs.

However, the package has a configuration in which the internal electrode provided on the base section and the external electrode provided on the bottom surface of the base section are connected via the conductive line that pierces through the base section (hereinafter referred to as a through-hole).

Therefore, compared with a configuration not including the through-hole, the package requires at least man-hour for providing the through-hole that pierces through the base section and man-hour for filling a conductor in the through-hole in order to secure air tightness of the package.

As a result, the manufacturing costs for the package are not sufficiently reduced.

Therefore, as measures for eliminating the through-hole of the package in order to further reduce the manufacturing costs, a configuration is conceivable in which a bonding material, which uses a metal metalized layer provided on the entire periphery of the base section, is replaced with an insulative bonding material, a wire is drawn out to the outer periphery of the base section, and the internal electrode and the external electrode are connected through a side surface of the base section.

However, in the package having this configuration, a section where the bonding material and the wire cross each other (the bonding material lies on top of the wire) (a crossing section) is inevitably formed.

Therefore, in the package having this configuration, it is likely that, for example, when low-melting glass having insulating properties is used in the bonding material, adhesion of the bonding material to a commonly used wire formed by laminating a Ni base layer and an Au covering layer on a metal metalized layer of W, Mo, or the like is poor in the crossing section and air tightness of the package cannot be secured.

### SUMMARY

An advantage of some aspects of the invention is to solve at least a part of the problems described above, and the invention can be implemented as the following forms or application examples.

### APPLICATION EXAMPLE 1

This application example of the invention is directed to a package including: a tabular base section, abase material of which is a single layer; a lid section that has a recess and covers the base section on an opening side of the recess; and a bonding material provided over the entire periphery of one principal plane of the base section and including low-melting glass for bonding the base section and the lid section. An internal electrode is provided on the one principal plane of the base section. An external electrode is provided on the other principal plane of the base section. At least a set of the internal electrode and the external electrode are connected to each other through a side surface of the base section, which joins the one principal plane and the other principal plane, by a wire drawn around to the one principal plane and the other principal plane. The wire contains an Ag—Pd alloy having a glass component and crosses the bonding material on the one principal plane.

According to this application example, in the package, the internal electrode is provided on the one principal plane of the base section, the external electrode is provided on the other principal plane, and the at least one set of the internal electrode and the external electrode are connected to each other through the side surface of the base section, which joins the one principal plane and the other principal plane, by the wire drawing around to the one principal plane and the other principal plane. The wire contains the Ag—Pd alloy having the glass component and, on the one principal plane, crosses (lies on top of) the bonding material including the low-melting glass.

Consequently, in the package, a through-hole necessary in the structure in the past to connect the internal electrode and the external electrode is unnecessary. Therefore, manufacturing man-hour can be reduced compared with the structure in the past. As a result, it is possible to attain a reduction in costs of the package.

In addition, in the package, the bonding material includes the low-melting glass and the wire contains the Ag—Pd alloy having the glass component. Therefore, the bonding material and the wire have a good affinity. Adhesion in a crossing section of the bonding material and the wire is extremely satisfactory.

Consequently, the package can sufficiently secure airtightness on the inside over the entire periphery including the crossing section.

### APPLICATION EXAMPLE 2

In the package according to the above application example, it is preferred that a plane shape of the base section is a substantially rectangular shape, and the wire crosses the bonding material at a first corner and a second corner located at one opposite angles of the base section.

In the package, the plane shape of the base section is the substantially rectangular shape and the wire crosses the bonding material at the first corner and the second corner located at the one opposite angles of the base section.

Consequently, in the package, for example, compared with a configuration in which the wire crosses the bonding material at corners adjacent to each other of the base section, the lid section can be bonded to the base section in a stable state with small inclination.

As a result, the package can surely secure air tightness on the inside.

### APPLICATION EXAMPLE 3

In the package according to Application Example 2, it is preferred that the other wire crosses the bonding material at a third corner and a fourth corner located at the other opposite angles of the base section.

In the package, the other wire crosses the bonding material at the third corner and the fourth corner located at the other opposite angles of the base section. Therefore, the wires and the bonding material cross each other at all the first to fourth corners of the base section.

Consequently, in the package, compared with the package in which the wires crosses the bonding material at the first corner and the second corner of the base section, the lid can be bonded to the base section in a more stable state.

As a result, the package can more surely secure air tightness on the inside.

### APPLICATION EXAMPLE 4

In the package according to the above application example, it is preferred that the wire is orthogonal to the bonding material.

In the package, since the wire is orthogonal to the bonding material, the length of the crossing section of the wire and the bonding material is the smallest.

Consequently, in the package, compared with a configuration in which the wire obliquely crosses the bonding material and the length of the crossing section of the wire and the bonding material is large, occurrence of a deficiency such as insufficient air tightness due to the crossing of the wire and the bonding material can be suppressed.

### APPLICATION EXAMPLE 5

This application example of the invention is directed to a resonator including: the package according to any of the above application examples; and a resonator element housed in the package.

According to this application example, the resonator includes the package according to any of the above application examples and the resonator element housed in the package. Therefore, it is possible to provide the resonator that attains the effects explained above.

### APPLICATION EXAMPLE 6

This application example of the invention is directed to an oscillator including: the package according to any of the above application examples; the resonator element housed in the package, and an oscillation circuit that causes the resonator element to oscillate.

According to this application example, the oscillator includes the package according to any of the above application examples, the resonator element housed in the package, and the oscillation circuit that causes the resonator element to oscillate. Therefore, it is possible to provide the oscillator that attains the effects explained above.

### APPLICATION EXAMPLE 7

This application example of the invention is directed to an electronic device including the resonator or the oscillator according to the above application example.

According to this application example, the electronic device includes the resonator or the oscillator according to the above application example. Therefore, it is possible to provide the electronic device that attains the effects explained above.

### BRIEF DESCRIPTION OF THE DRAWINGS

The invention will be described with reference to the accompanying drawings, wherein like numbers reference like elements.

FIGS. 1A to 1C are schematic diagrams showing a schematic configuration of a quartz resonator according to a first embodiment, wherein FIG. 1A is a front plan view of the quartz resonator overlooked from a lid section side, FIG. 1B is a sectional view of the quartz resonator taken along a line A-A in FIG. 1A, and FIG. 1C is a rear plan view of the quartz resonator seen through from the lid section side.

FIGS. 2A to 2C are schematic diagrams showing a schematic configuration of a quartz resonator according to a modification 1, wherein FIG. 2A is a front plan view of the quartz resonator overlooked from a lid section side, FIG. 2B is a sectional view of the quartz resonator taken along a line B-B in FIG. 2A, and FIG. 2C is a rear plan view of the quartz resonator seen through from the lid section side.

FIGS. 3A to 3C are schematic diagrams showing a schematic configuration of a quartz resonator according to a modification 2, wherein FIG. 3A is a front plan view of the quartz resonator overlooked from a lid section side, FIG. 3B is a sectional view of the quartz resonator taken along a line A-A in FIG. 3A, and FIG. 3C is a rear plan view of the quartz resonator seen through from the lid section side.

FIGS. 4A to 4C are schematic diagrams showing a schematic configuration of a quartz oscillator according to a second embodiment, wherein FIG. 4A is a front plan view of the quartz oscillator overlooked from a lid section side, FIG. 4B is a sectional view of the quartz oscillator taken along a line C-C in FIG. 4A, and FIG. 4C is a rear plan view seen through from the lid section side.

FIG. 5 is a schematic perspective view showing a cellular phone according to a third embodiment.

### DESCRIPTION OF EXEMPLARY EMBODIMENTS

Embodiments of the invention are explained below with reference to the accompanying drawings.

### First Embodiment

First, a quartz resonator as an example of a resonator is explained.

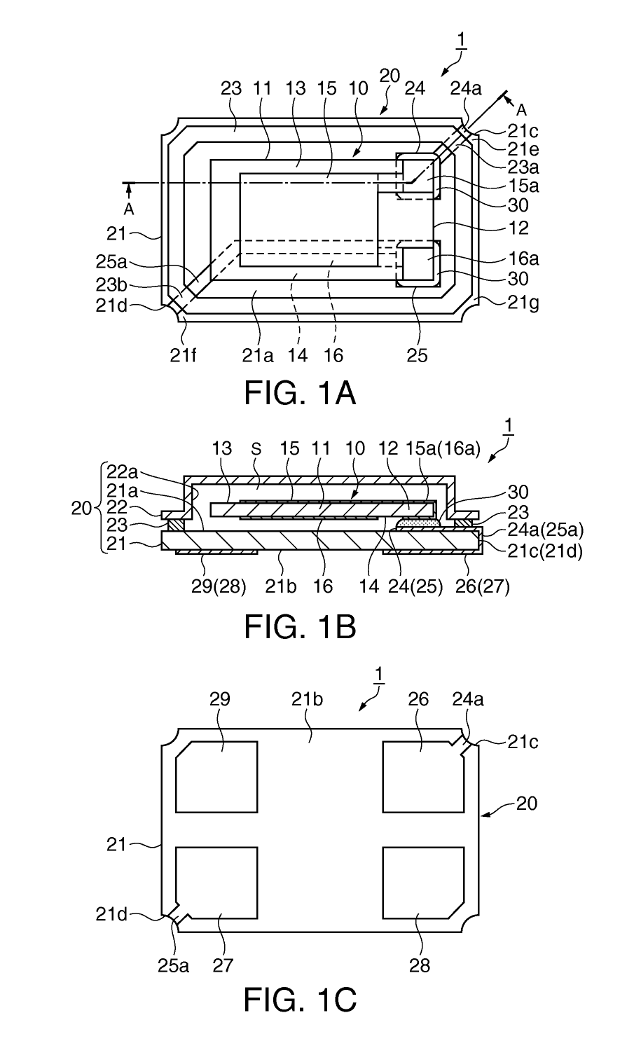

FIGS. 1A to 1C are schematic diagrams showing a schematic configuration of a quartz resonator according to a first embodiment. FIG. 1A is a front plan view of the quartz resonator overlooked from a lid section side. FIG. 1B is a sectional view of the quartz resonator taken along a line A-A in FIG. 1A. FIG. 1C is a rear plan view of the quartz resonator seen through from the lid section side. In the front plan view, the lid section is not shown. A dimension ratio of components is different from an actual dimension ratio.

As shown in FIGS. 1A to 1C, a quartz resonator 1 includes a quartz resonator element 10 functioning as a resonator element and a package 20 that houses the quartz resonator element 10.

The quartz resonator element 10 is an AT cut type carved out from, for example, an ore of quartz crystal at a predetermined angle. A plane shape of the quartz resonator element 10 is formed in a rectangular shape. The quartz resonator element 10 includes a vibrating section 11 that performs thickness slip vibration and a base 12 connected to the vibrating section 11.

In the quartz resonator element 10, extraction electrodes 15a and 16a extracted from excitation electrodes 15 and 16 formed on one principal plane 13 and the other principal plane 14 of the vibrating section 11 are formed on the base 12.

The extraction electrode 15a is extracted to the base 12 from the excitation electrode 15 on the one principal plane 13 along a longitudinal direction of the quartz resonator element 10 (left and right directions on the paper surface), routed around to the other principal plane 14 through a side surface of the base 12, and extended to the vicinity of the excitation electrode 16 on the other principal plane 14.

The extraction electrode 16a is extracted to the base 12 from the excitation electrode 16 on the other principal plane 14 along the longitudinal direction of the quartz resonator element 10, routed around to the one principal plane 13 through a side surface of the base 12, and extended to the vicinity of the excitation electrode 15 on the one principal plane 13.

The excitation electrodes 15 and 16 and the extraction electrodes 15a and 16a are formed as, for example, a metal coating formed by laminating Au on a base layer of Cr.

The package 20 includes a tabular base section 21, a base material (a main material) of which is a single layer and a plane shape of which is a substantially rectangular shape, a lid section 22 that has a recess 22a, in which an inner space S is formed, and covers the base section 21 on an opening side of the recess 22a, and a bonding material 23 provided over the entire periphery of an outer peripheral portion on one principal plane 21a of the base section 21 and including low-melting glass that joins the base section 21 and the lid section 22.

In the base section 21, an aluminum oxide sintered body obtained by molding and sintering a ceramic green sheet, quartz crystal, glass, silicon, or the like of a single layer is used.

In the lid section 22, a material same as the material of the base section 21 or metal such as Kovar (an Fe—Ni—Co alloy), a 42 alloy (an Fe—Ni alloy), or SUS 304 (stainless steel) is used.

In the base section 21, substantially rectangular internal electrodes 24 and 25 that support the quartz resonator element 10 housed on the inside (the inner space S) of the package 20 are provided on the one principal plane 21a. Substantially rectangular external electrodes 26, 27, 28, and 29 used when the base section 21 is mounted on an external member such as an electronic device are provided on the other principal plane 21b along corners of the base section 21.

The internal electrode 24 and the external electrode 26 are connected to each other by a wire 24a drawn around to the one principal plane 21a and the other principal plane 21b through a side surface 21c of the base section 21, which joins the one principal plane 21a and the other principal plane 21b.

On the other hand, the internal electrode 25 and the external electrode 27 are connected to each other by a wire 25a drawn around to the one principal plane 21a and the other principal plane 21b through a side surface 21d of the base section 21, which joins the one principal plane 21a and the other principal plane 21b.

Consequently, the wires 24a and 25a cross the bonding material 23 at a first corner 21e and a second corner 21f located at one opposite angles of the base section 21.

The external electrodes 28 and 29 are independently arranged without being connected to other portions. The external electrodes 28 and 29 are used as, for example, fixing electrodes when the base section 21 is mounted on the external member.

The internal electrodes 24 and 25, the external electrodes 26, 27, 28, and 29, and the wires 24a and 25a contain an Ag—Pd alloy having a glass component and are applied by screen printing or the like in a paste state and then heated and hardened in a sintering furnace.

A Pd content in the Ag—Pd alloy having the glass component is desirably about 3% to 20% in a weight ratio when adhesion to the bonding material 23, reliability and costs in mounting on the external member, and the like are taken into account.

For example, the wires 24a and 25a are printed to overhang from the one principal plane 21a and the other principal plane 21b to the side surfaces 21c and 21d side. Overhanging portions are sucked to droop to be routed around to the side surfaces 21c and 21d, whereby the one principal plane 21a side and the other principal plane 21b side are joined.

The bonding material 23 including the low-melting glass has a melting point (a softening point) of, for example, about 320° C. to 380° C. After the wires 24a and 25a are formed, the bonding material 23 is applied to the entire periphery of the outer peripheral portion of the one principal plane 21a of the base section 21 by the screen printing or the like in a paste state and then heated and hardened in the sintering furnace.

In the bonding material 23, for example, barium oxide (BaO)-lead monoxide (PbO) low-melting glass or bismuth low-melting glass of a lead-free type is used.

As explained above, the wires 24a and 25a cross the bonding material 23 including the low-melting glass on the one principal plane 21a (the bonding material 23 lies on top of the wires 24a and 25a (on the lid section 22 side).

Specifically, at the first corner 21e, the wire 24a is orthogonal to, in a crossing section 23a, a portion that joins, in a chamfered shape, a portion extending along one long side and a portion extending along one short side of the one principal plane 21a in the bonding material 23.

On the other hand, at the second corner 21f, the wire 25a is orthogonal to, in a crossing section 23b, a portion that joins, in a chambered shape, a portion extending along the other long side and a portion extending along the other short side of the one principal plane 21a in the bonding material 23.

In the package 20, if possible, only the wires 24a and 25a may be formed of a material containing the Ag—Pd alloy having the glass component and the internal electrodes 24 and 25 and the external electrodes 26, 27, 28, and 29 may be formed of a metal metalized layer of W, Mo, or the like not containing the Ag—Pd alloy having the glass component.

In the quartz resonator 1, the quartz resonator element 10 is supported by the internal electrodes 24 and 25 via a bonding member 30 such as a conductive adhesive or solder. Consequently, the excitation electrodes 15 and 16 of the quartz resonator element 10 are electrically connected to the internal electrodes 24 and 25 through the extraction electrodes 15a and 16a and the bonding member 30.

In the quartz resonator 1, in a state in which the quartz resonator element 10 is supported by the internal electrodes 24 and 25 of the base section 21, the base section 21 is covered with the lid section 22 and the base section 21 and the lid section 22 are bonded by the bonding material 23, whereby the inside (the inner space S) of the package 20 is hermetically sealed.

The inside of the package 20 is in a vacuum state (a state of a high degree of vacuum) or a state in which an inert gas such as helium or argon is filled.

In the quartz resonator 1, the vibrating section 11 of the quartz resonator element 10 is excited by a driving signal applied from the outside through the external electrodes 26 and 27, the internal electrodes 24 and 25, the bonding member 30, the extraction electrodes 15a and 16a, and the excitation electrodes 15 and 16 and oscillates (resonates) at a predetermined frequency.

As explained above, in the quartz resonator 1 according to the first embodiment, the internal electrodes 24 and 25 are provided on the one principal plane 21a and the external electrodes 26 and 27 are provided on the other principal plane 21b of the base section 21 of the package 20. The internal electrodes 24 and 25 and the external electrodes 26 and 27 are connected to each other by the wires 24a and 25a drawn around to the one principal plane 21a and the other principal plane 21b through the side surfaces 21c and 21d of the base section 21, which join the one principal plane 21a and the other principal plane 21b.

In the quartz resonator 1, the wires 24a and 25a contain the Ag—Pd alloy having the glass component and cross the bonding material 23 including the low-melting glass on the one principal plane 21a.

Consequently, in the package 20 of the quartz resonator 1, a through-hole necessary in the structure in the past is unnecessary for the connection of the internal electrodes 24 and 25 and the external electrodes 26 and 27. Therefore, manufacturing man-hour can be reduced compared with the structure in the past. As a result, the package 20 of the quartz resonator 1 can realize a reduction in costs.

Therefore, the quartz resonator 1 can realize the reduction in costs.

In addition, in the package 20 of the quartz resonator 1, the bonding material 23 includes the low-melting glass and the wires 24a and 25a contain the Ag—Pd alloy having the glass component. Therefore, the bonding material 23 and the wires 24a and 25a have a good affinity. Adhesion in the crossing sections 23a and 23b of the bonding material 23 and the wires 24a and 25a is extremely satisfactory.

Consequently, the package 20 of the quartz resonator 1 can sufficiently secure air tightness on the inside (the inner space S) over the entire periphery including the crossing sections 23a and 23b.

Therefore, the quartz resonator 1 can sufficiently secure the air tightness.

In the package 20 of the quartz resonator 1, since the wires 24a and 25a are orthogonal to the bonding material 23 in the crossing sections 23a and 23b, the length of crossing (overlap) of the wires 24a and 25a and the bonding material 23 is the smallest.

Consequently, in the package 20 of the quartz resonator 1, compared with a configuration in which the wires 24a and 25a obliquely cross the bonding material 23 and the length of crossing of the wires 24a and 25a and the bonding material 23 is large, occurrence of a deficiency such as deterioration in air tightness due to the crossing of the wires 24a and 25a and the bonding material 23 can be suppressed.

Therefore, the quartz resonator 1 can suppress the occurrence of the deficiency such as deterioration in air tightness.

In the package 20 of the quartz resonator 1, the plane shape of the base section 21 is the substantially rectangular shape. The wires 24a and 25a cross the bonding material 23 at the first corner 21e and the second corner 21f located at the one opposite angles of the base section 21.

Therefore, in the package 20 of the quartz resonator 1, for example, compared with a configuration in which the wires 24a and 25a cross the bonding material 23 at corners adjacent to each other (e.g., the first corner 21e and a third corner 21g) of the base section 21, the lid section 22 can be bonded to the base section 21 in a stable state with small inclination.

As a result, the package 20 of the quartz resonator 1 can surely secure air tightness on the inside.

Therefore, the quartz resonator 1 can surely secure the air tightness.

In the package 20 of the quartz resonator 1, the wires 24a and 25a and the bonding material 23 may obliquely cross each other. A configuration of the oblique crossing can also be applied to modifications and embodiments explained later.

Modifications of the first embodiment are explained below.

### Modification 1

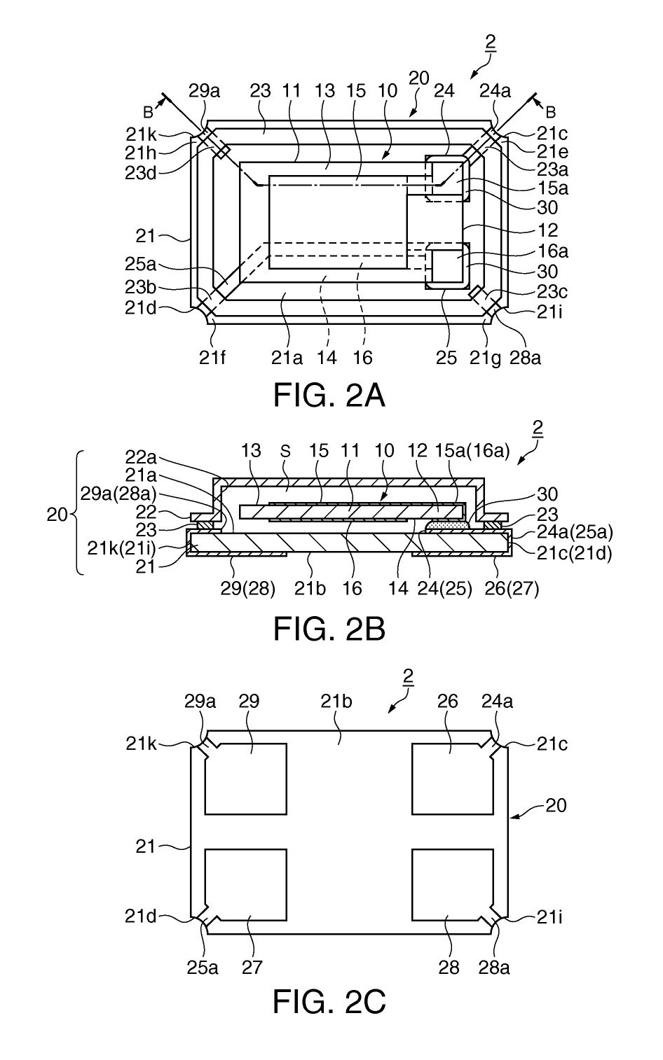

FIGS. 2A to 2C are schematic diagrams showing a schematic configuration of a quartz resonator according to a modification 1. FIG. 2A is a front plan view of the quartz resonator overlooked from a lid section side. FIG. 2B is a sectional view of the quartz resonator taken along a line B-B in FIG. 2A. FIG. 2C is a rear plan view of the quartz resonator seen through from the lid section side. In the front plan view, the lid section is not shown. A dimension ratio of components is different from an actual dimension ratio. Components same as those in the first embodiment are denoted by the same reference numerals and signs and detailed explanation of the components is omitted. Differences from the first embodiment are mainly explained.

As shown in FIGS. 2A to 2C, in a quartz resonator 2, wires 28a and 29a functioning as the other wires are drawn around to the one principal plane 21a and the other principal plane 21b through side surfaces 21i and 21k of the base section 21 of the package 20 that join the one principal plane 21a and the other principal plane 21b. The wires 28a and 29a are connected to the external electrodes 28 and 29 on the other principal plane 21b. The wires 28a and 29a cross the bonding material 23 at the third corner 21g and a fourth corner 21h located at the other opposite angles of the one principal plane 21a of the base section 21.

Specifically, at the third corner 21g, the wire 28a is orthogonal to, in a crossing section 23c, a portion that joins, in a chamfered shape, a portion extending along one long side and a portion extending along one short side of the one principal plane 21a in the bonding material 23.

On the other hand, at the fourth corner 21h, the wire 29a is orthogonal to, in a crossing section 23d, a portion that joins, in a chambered shape, a portion extending along the other long side and a portion extending along the other short side of the one principal plane 21a in the bonding material 23.

The wires 28a and 29a extend to a position slightly further on the inner side than the bonding material 23 on the one principal plane 21a.

As explained above, in the package 20 of the quartz resonator 2, the wires 28a and 29a cross the bonding material 23 at the third corner 21g and the fourth corner 21h located at the other opposite angles of the base section 21. Therefore, the wires 24a, 25a, 28a, and 29a and the bonding material 23 cross each other at all the first corner 21e to the fourth corner 21h of the base section 21.

Consequently, in the package 20 of the quartz resonator 2, compared with the first embodiment, the lid section 22 can be bonded to the base section 21 in a more stable state.

As a result, the package 20 of the quartz resonator 2 can more surely secure air tightness on the inside.

Therefore, the quartz resonator 2 can more surely secure the air tightness.

### Modification 2

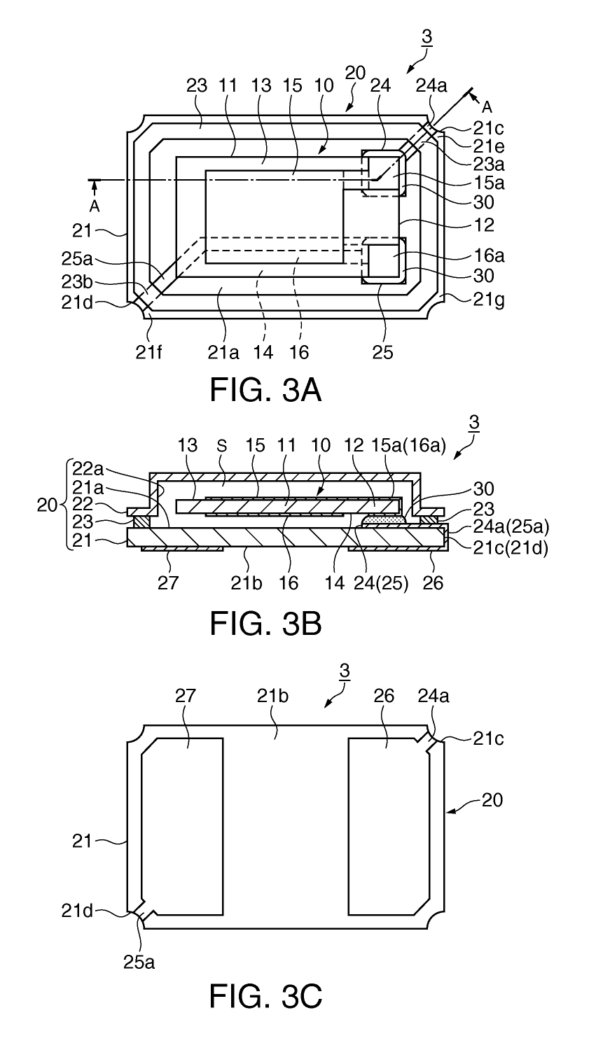

FIGS. 3A to 3C are schematic diagrams showing a schematic configuration of a quartz resonator according to a modification 2. FIG. 3A is a front plan view of the quartz resonator overlooked from a lid section side. FIG. 3B is a sectional view of the quartz resonator taken along a line A-A in FIG. 3A. FIG. 3C is a rear plan view of the quartz resonator seen through from the lid section side. In the front plan view, the lid section is not shown. A dimension ratio of components is different from an actual dimension ratio. Components same as those in the first embodiment are denoted by the same reference numerals and signs and detailed explanation of the components is omitted. Differences from the first embodiment are mainly explained.

As shown in FIGS. 3A to 3C, in a quartz resonator 3, the external electrodes 28 and 29 (see FIGS. 1A to 1C) are removed. The external electrodes 26 and 27 extend to spaces of the external electrodes 28 and 29.

Consequently, in the quartz resonator 3, the area of the external electrodes 26 and 27 of the base section 21 of the package 20 increases. Therefore, compared with the first embodiment, for example, a probe of an inspection device can be easily brought into contact with the external electrodes 26 and 27 and a characteristic inspection and the like can be easily performed.

In the quartz resonator 3, since the area of the external electrodes 26 and 27 of the base section 21 of the package 20 increases, compared with the first embodiment, it is possible to improve reliability of connection during mounting on the external member.

### Second Embodiment

A quartz oscillator as an example of an oscillator is explained.

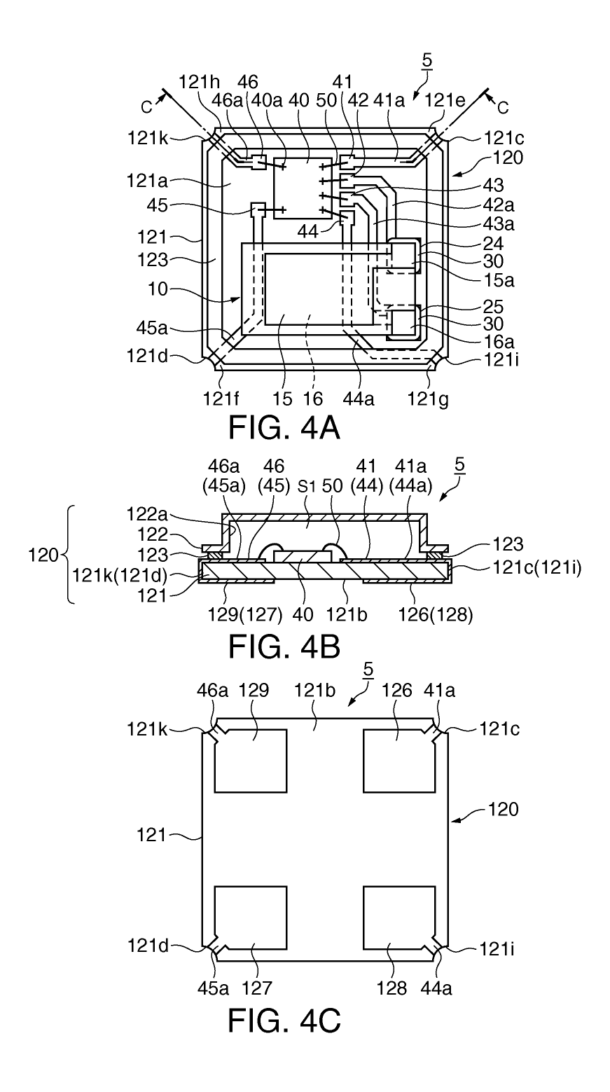

FIGS. 4A to 4C are schematic diagrams showing a schematic configuration of a quartz oscillator according to a second embodiment. FIG. 4A is a front plan view of the quartz oscillator overlooked from a lid section side. FIG. 4B is a sectional view of the quartz oscillator taken along a line C-C in FIG. 4A. FIG. 4C is a rear plan view seen through from the lid section side. In the front plan view, the lid section is not shown. A dimension ratio of components is different from an actual dimension ratio. Components same as those in the first embodiment are denoted by the same reference numerals and signs and detailed explanation of the components is omitted. Differences from the first embodiment are mainly explained. Concerning a sectional shape around a quartz resonator element, see FIG. 1B.

As shown in FIGS. 4A to 4C, a quartz oscillator 5 includes the quartz resonator element 10, a package 120 that houses the quartz resonator element 10, and an IC chip 40 functioning as an oscillation circuit that causes the quartz resonator element 10 to oscillate (resonate).

In the quartz oscillator 5, the quartz resonator element 10 and the IC chip 40 are arranged not to planarly overlap. Therefore, for example, compared with the quartz resonator 1 according to the first embodiment, a plane size is large. However, the quartz oscillator 5 is equal to the quartz resonator 1 in thickness.

The package 120 includes a tabular base section 121, a base material of which is a single layer and a plane shape of which is a substantially rectangular shape, a lid section 122 that has a recess 122a, in which an inner space S1 is formed, and covers the base section 121 on an opening side of the recess 122a, and a bonding material 123 provided over the entire periphery of an outer peripheral portion in one principal plane 121a of the base section 121 and including low-melting glass that joins the base section 121 and the lid section 122.

The materials of the base section 121 and the lid section 122 are the same as the materials of the base section 21 and the lid section 22 in the first embodiment. Therefore, explanation of the materials is omitted.

In the base section 121, substantially rectangular internal electrodes 41, 42, 43, 44, 45, and 46 connected to a connection pad 40a (simply indicated by +) of the IC chip 40 are provided on the one principal plane 121a in addition to the internal electrodes 24 and 25 that support the quartz resonator element 10 housed on the inside (the inner space S1) of the package 120. Substantially rectangular external electrodes 126, 127, 128, and 129 used in mounting the base section 121 on an external member such as an electronic device are provided on the other principal plane 121b to extend along corners of the base section 121.

The internal electrodes 24 and 25 are respectively connected to the internal electrodes 42 and 43 by wires 42a and 43a drawn around to the one principal plane 121a of the base section 121.

The internal electrode 41 and the external electrode 126 are connected to each other by a wire 41a drawn around to the first principal plane 121a and the other principal plane 121b through a side surface 121c, which joins the one principal plane 121a and the other principal plane 121b of the base section 121.

The internal electrode 44 and the external electrode 128 are connected to each other by a wire 44a drawn around to the one principal plane 121a and the other principal plane 121b through a side surface 121i, which joins the one principal plane 121a and the other principal plane 121b of the base section 121.

Further, the internal electrode 45 and the external electrode 127 are connected to each other by a wire 45a drawn around to the one principal plane 121a and the other principal plane 121b through a side surface 121d, which joins the one principal plane 121a and the other principal plane 121b of the base section 121.

In addition, the internal electrode 46 and the external electrode 129 are connected to each other by a wire 46a drawn around to the one principal plane 121a and the other principal plane 121b through a side surface 121k, which joins the one principal plane 121a and the other principal plane 121b of the base section 121.

Consequently, the wires 41a and 45a cross the bonding material 123 at a first corner 121e and a second corner 121f located at one opposite angles of the base section 121 and the wires 44a and 46a cross the bonding material 123 at a third corner 121g and a fourth corner 121h located at the other opposite angles of the base section 121 (in other words, the bonding material 123 lies on top of the wires 41a, 44a, 45a, and 46a (on the lid section 122 side)).

The internal electrodes 24, 25, 41, 42, 43, 44, 45, and 46, the external electrodes 126, 127, 128, and 129, and the wires 41a, 42a, 43a, 44a, 45a, and 46a contain an Ag—Pd alloy having a glass component and are applied by screen printing or the like in a paste state and then heated and hardened in a sintering furnace.

A Pd content in the Ag—Pd alloy having the glass component is desirably about 3% to 20% in a weight ratio when adhesion to the bonding material 123, reliability and costs in mounting on the external member, and the like are taken into account.

The bonding material 123 including the low-melting glass has a melting point (a softening point) of, for example, about 320° C. to 380° C. After the wires 41a, 44a, 45a, and 46a are formed, the bonding material 123 is applied to the entire periphery of the outer peripheral portion of the one principal plane 121a of the base section 121 by the screen printing or the like in a paste state and then heated and hardened in the sintering furnace.

In the bonding material 123, for example, barium oxide (BaO)-lead monoxide (PbO) low-melting glass or bismuth low-melting glass of a lead-free type is used.

In the quartz oscillator 5, the quartz resonator element 10 is supported by the internal electrodes 24 and 25 via the bonding member 30 such as a conductive adhesive or solder. Consequently, the excitation electrodes 15 and 16 of the quartz resonator element 10 are electrically connected to the internal electrodes 24 and 25 through the extraction electrodes 15a and 16a and the bonding member 30.

The IC chip 40 incorporating an oscillation circuit is fixed to the one principal plane 121a of the base section 121 using a not-shown adhesive or the like.

In the IC chip 40, the connection pad 40a is connected to the internal electrodes 41, 42, 43, 44, 45, and 46 by a metal wire 50 of Au, Al, or the like.

For connection of the connection pad 40a of the IC chip 40 and the internal electrodes 41, 42, 43, 44, 45, and 46, besides a connection method by wire bonding using the metal wire 50, for example, a connection method by flip-chip mounting performed by reversing the IC chip 40 may be used.

In the quartz oscillator 5, in a state in which the quartz resonator element 10 is supported by the internal electrodes 24 and 25 of the base section 121 and the IC chip 40 is connected to the internal electrodes 41, 42, 43, 44, 45, and 46, the base section 121 is covered with the lid section 122 and the base section 121 and the lid section 122 are bonded by the bonding material 123, whereby the inside (the inner space S1) of the package 120 is hermetically sealed.

The inside of the package 120 is in a vacuum state (a state of a high degree of vacuum) or a state in which an inert gas such as helium or argon is filled.

In the quartz oscillator 5, the quartz resonator element 10 oscillates (resonates) at a predetermined frequency with a driving signal applied from the IC chip 40 through the metal wire 50, the internal electrodes 42 and 43, the wires 42a and 43a, the internal electrodes 24 and 25, the bonding member 30, the extraction electrodes 15a and 16a, and the excitation electrodes 15 and 16.

The quartz oscillator 5 outputs an oscillation signal generated by the oscillation to the outside through the IC chip 40, the metal wire 50, anyone (e.g., 46) of the internal electrodes 41, 44, 45, and 46, any one (e.g., 129) of the external electrodes 126, 127, 128, and 129, and the like.

The external electrodes (e.g., 126, 127, and 128) other than the external electrodes for output function as, for example, signal terminals for a power supply, a GND, and an input (a control input for ON/OFF of an output).

As explained above, in the quartz oscillator 5 according to the second embodiment, the quartz resonator element 10 and the IC chip 40 are housed in the package 120 including the base section 121 of the single layer configuration. Therefore, it is possible to provide an oscillator that realizes effects same as the effects explained in the first embodiment and the modification 1 (e.g., an oscillator that can realize a reduction in costs).

The quartz oscillator 5 may be configured in a module structure in which the IC chip 40 is externally attached to the package 120 rather than being incorporated in the package 120 (e.g., a quartz resonator and an IC chip are separately mounted on one substrate).

### Third Embodiment

A cellular phone functioning as an electronic device including the quartz resonator (the resonator) explained in the first embodiment and the modifications or the quartz oscillator (the oscillator) explained in the second embodiment is explained.

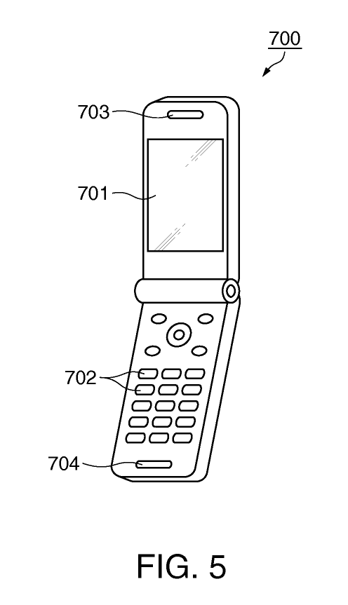

FIG. 5 is a schematic perspective view showing a cellular phone according to a third embodiment.

A cellular phone 700 shown in FIG. 5 includes any one of the quartz resonators 1 to 3 or the quartz oscillator 5 explained in the embodiments and the modifications as a reference clock oscillation source or the like and further includes a liquid crystal display device 701, plural operation buttons 702, an earpiece 703, and a mouthpiece 704.

The quartz resonators 1 to 3 or the quartz oscillator 5 can be suitably used not only as the cellular phone but also as the reference clock oscillation source or the like of, for example, an electronic book, a personal computer, a television, a digital still camera, a video camera, a video recorder, a navigation apparatus, a pager, an electronic organizer, an electric calculator, a word processor, a work station, a television telephone, a POS terminal, and an apparatus including a touch panel. In any case, it is possible to provide an electronic device that realizes the effects explained in the embodiments and the modifications.

The base material of the resonator element is not limited to quartz crystal and may be a piezoelectric material such as lithium tantalate (LiTaO₃), lithium tetraborate (Li₂B₄O₇), lithium niobate (LiNbO₃), lead zirconate titanate (PZT), zinc oxide (ZnO), or aluminum nitride (AlN) or a semiconductor material such as silicon.

The entire disclosure of Japanese Patent Application No. 2011-085160, filed Apr. 7, 2011 is expressly incorporated by reference herein.

What is claimed is:

1. A base substrate for an electronic device, comprising:
a tabular base material of a single layer;
an electrode for mounting an electronic component, a bonding material arranged to surround the electrode and including low-melting glass, and a wire that is connected to the electrode for mounting the electronic component and crosses the bonding material, the electrode, the bonding material, and the wire being provided on one principal plane of the base material; and
an electrode for mounting the base substrate, the electrode being provided on other principal plane, wherein
the wire contains an Ag—Pd alloy having a glass component.

2. The base substrate according to claim 1, further comprising a wire that connects, through a side that joins the one principal plane and the other principal plane, the electrode for mounting the electronic component and the electrode for mounting the base substrate.

3. The base substrate according to claim 1, wherein
a plane shape of the base substrate is a substantially rectangular shape, and
the wire crosses the bonding material at two corners located at one opposite angles of the base substrate.

4. The base substrate according to claim 1, wherein
a plane shape of the base substrate is a substantially rectangular shape, and
the wire crosses the bonding material at four corners of the base substrate.

5. The base substrate according to claim 1, wherein the wire is orthogonal to the bonding material.

6. A resonator comprising:
the base substrate according to claim 1;
a resonator element functioning as the electronic component mounted on the base substrate; and
a lid that houses the resonator element together with the base substrate.

7. A resonator comprising:
the base substrate according to claim 2;
a resonator element functioning as the electronic component mounted on the base substrate; and
a lid that houses the resonator element together with the base substrate.

8. An oscillator comprising:
the base substrate according to claim 1;
a resonator element functioning as the electronic component mounted on the base substrate;
a lid that houses the resonator element together with the base substrate; and
an oscillation circuit that causes the resonator element to oscillate.

9. An oscillator comprising:
the base substrate according to claim 2;
a resonator element functioning as the electronic component mounted on the base substrate;
a lid that houses the resonator element together with the base substrate; and
an oscillation circuit that causes the resonator element to oscillate.

10. An electronic device comprising the base substrate according to claim 1.
